(19) United States
(12) Patent Application Publication
(10) Pub. No.: US 2002/0089025 A1
(43) Pub. Date: Jul. 11, 2002

(54) Package structure for image IC

(76) Inventor: Li-Kun Chou, Taipei Hsien (TW)

Correspondence Address: Rosenberg, Klein & Lee, Suite 101, 3458 Ellicott Center Drive, Ellicott City, MD, 21043, US

(21) Appl. No.: 09/754,270

(22) Filed: Jan. 5, 2001

(51) Int. Cl. H01L 23/02

(52) U.S. Cl. 257/433; 257/434; 257/680; 257/687; 257/787

(57) ABSTRACT

A package structure for an image IC comprises a leadframe, a dam and a glass cap. The CMOS image IC is mounted on center of the leadframe and adhered to the leadframe. The bottom of the CMOS image IC is adhered to the leadframe by binding paste. The outer leads of the leadframe are electrically connected to corresponding bond pads of the CMOS image IC through metal wire. A rectangular dam is provided on the outer leads and around the leadframe. Furthermore, a glass cap is placed atop the dam to complete the package.

### FIELD OF THE INVENTION

The present invention relates to a package structure for an image IC, especially to a package structure for an image IC, which uses lead frame to replace substrate.

### BACKGROUND OF THE INVENTION

Over the past decade, packaging becomes increasingly important for microelectronic devices. The quality of package often has influence on performance of microelectronic devices. The important issues such as size, weight, cost, pin count, delay time and power consumption should be taken into account. Therefore, a satisfactory package should be designed in view of material, structure, and electrical characteristic and at least cost.

FIG. 1 shows a sectional view of a conventional QFN package structure. As shown in this figure, the die 61 to be packages is mounted on and adhered to a substrate 60 of a leadframe 63. The substrate 60 has area larger than that of the die 61. The die 61 has bond pads (not shown) electrically connected to the leads (not shown) of the leadframe through metal wire such as Au—Al wire 62. Afterward, an epoxy resin 64 is used to encapsulate the resulting structure to protect the die 61 and the Au—Al wire 62.

FIG. 2 shows a sectional view of a package structure for a conventional CMOS image IC. As shown in this figure, the CMOS image IC 81 to be packages is mounted on and adhered to a substrate 80 with area larger than that of the CMOS image IC 81. The CMOS image IC 81 has bond pads (not shown) electrically connected to the leads (not shown) of the substrate 80 through metal wire such as Au—Al wire 82. Moreover, a rectangular castle 83 around the substrate 80 and a transparent cap 84 is placed atop the castle 83.

The materials of above-mentioned substates60 and 80 can adopt FRP board, ceramic board or other boards with similar effect such as BT or FR-4 boards.

### SUMMARY OF THE INVENTION

It is an object of the present invention to provide a package structure for an image IC, which uses lead frame to replace substrate. The CMOS image IC is mounted on center of the leadframe and adhered to the leadframe. The bottom of the CMOS image IC is adhered to the leadframe by binding paste. The outer leads of the leadframe are electrically connected to corresponding bond pads of the CMOS image IC through metal wire. A rectangular dam is provided on the outer leads and around the leadframe. Furthermore, a glass cap is placed atop the dam to complete the package.

It is another object of the present invention to provide a package structure for an image IC, which uses lead frame to replace substrate. The CMOS image IC is mounted on center of the leadframe and adhered to the leadframe. The bottom of the CMOS image IC is adhered to the leadframe by binding paste. The outer leads of the leadframe are electrically connected to corresponding bond pads of the CMOS image IC through metal wire. A transparent encapsulation is applied over the leadframe to protect the CMOS image IC and the metal wire.

The various objects and advantages of the present invention will be more readily understood from the following detailed description when read in conjunction with the appended drawing, in which:

### BRIEF DESCRIPTION OF DRAWING

FIG. 1 shows a sectional view of a prior art QFN package structure.

FIG. 2 shows a sectional view of a package structure for a prior art CMOS image IC.

FIG. 3 shows a preferred embodiment of the present invention.

FIG. 4 shows another preferred embodiment of the present invention.

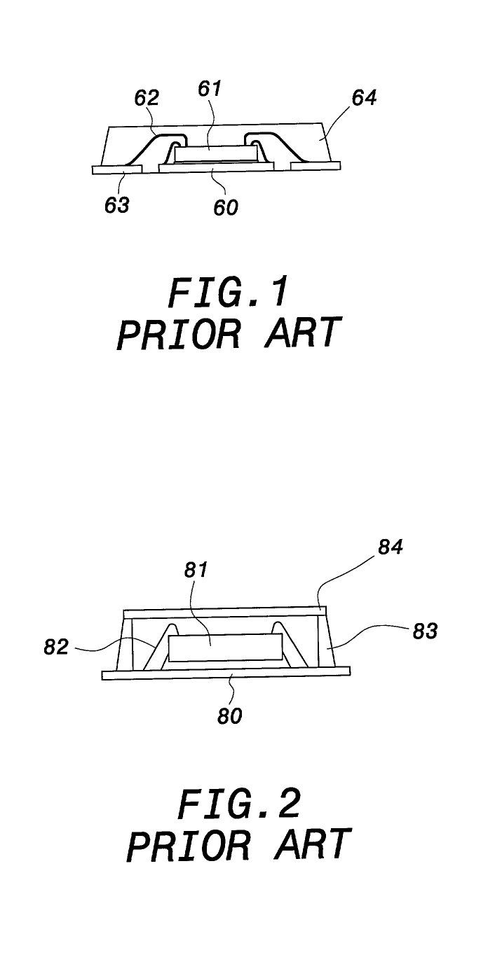

### DETAILED DESCRIPTION OF THE INVENTION

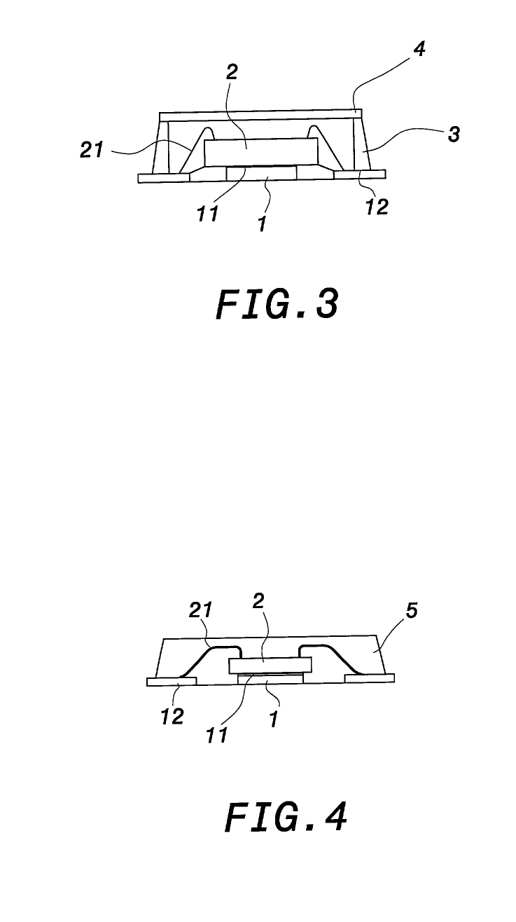

With reference now to FIG. 3, the present invention provides a package structure for an image IC. The package structure comprises a leadframe 1, a dam 3 and a glass cap 4, and used to package a CMOS image IC 2.

The CMOS image IC 2 is mounted on center of the leadframe 1 and adhered to the leadframe 1. The bottom of the CMOS image IC 2 is adhered to the leadframe 1 by binding paste such as silver epoxy 11. The leadframe 1 has a plurality of outer leads 12 extended toward the CMOS image IC 2. The outer leads 12 are electrically connected to corresponding bond pads (not shown) of the CMOS image IC 2 through metal wire 21. A dam 3 of predetermined height and thickness is provided on the outer leads 12 and around the leadframe 1. Furthermore, a glass cap 4 is placed atop the dam 3 to complete the package.

With reference now to FIG. 4, this figure shows another preferred embodiment of the present invention. The CMOS image IC 2 is mounted on center of the leadframe 1 and adhered to the leadframe 1. The bottom of the CMOS image IC 2 is adhered to the leadframe 1 by binding paste such as silver epoxy 11. The leadframe 1 has a plurality of outer leads 12 extended toward the CMOS image IC 2. The outer leads 12 are electrically connected to corresponding bond pads (not shown) of the CMOS image IC 2 through metal wire 21. An epoxy resin is applied over the CMOS image IC 2 to form an encapsulation 5 to protect the CMOS image IC 2 and the metal wire 21.

To sum up, the package structure for image IC according to the present invention has following advantages:

(1). The cost is greatly reduced by using leadframe to replace expensive substrate.

(2). The thickness is thinner.

(3). The suppliers for leadframe is abundant, this component is safe from shortage.

(4). This kind of package is more suitable for mass production.

(5). This kind of package is more suitable for digital still camera (DSC) and communication devices.

Although the present invention has been described with reference to the preferred embodiment thereof, it will be understood that the invention is not limited to the details thereof. Various substitutions and modifications have suggested in the foregoing description, and other will occur to those of ordinary skill in the art. Therefore, all such substitutions and modifications are intended to be embraced within the scope of the invention as defined in the appended claims.

I claim:

1. A package structure for image IC, comprising
a CMOS image IC having a plurality of bond pads;
a leadframe at center part thereof the CMOS image IC being mounted; the leadframe having a plurality of outer leads extending toward the CMOS image IC; the outer leads electrically connected to corresponding bond pads of the CMOS image IC through metal wire;
a dam provided on the outer leads and around the leadframe; and
a glass cap placed atop the dam.

2. A package structure for image IC, comprising
a CMOS image IC having a plurality of bond pads;
a leadframe at center part thereof the CMOS image IC being mounted; the leadframe having a plurality of outer leads extending toward the CMOS image IC; the outer leads electrically connected to corresponding bond pads of the CMOS image IC through metal wire; and
a transparent encapsulation over the leadframe to protect the CMOS image IC and the metal wire.
